(19) United States
(12) Patent Application Publication
(10) Pub. No.: US 2024/0224779 A1
(43) Pub. Date: Jul. 4, 2024

(54) POLYMER, ORGANIC SEMICONDUCTOR MATERIAL, THIN FILM, AND ELECTRONIC DEVICE

(71) Applicant: Samsung Electronics Co., Ltd., Suwon-si, Gyeonggi-do (KR)

(72) Inventors: Sangah GAM, Suwon-si (KR); Jiyoung JUNG, Suwon-si (KR); Youngjun YUN, Suwon-si (KR); Gae Hwang LEE, Suwon-si (KR); Bang-Lin LEE, Suwon-si (KR); Ajeong CHOI, Suwon-si (KR)

(73) Assignee: Samsung Electronics Co., Ltd., Suwon-si, Gyeonggi-do (KR)

(21) Appl. No.: 18/390,885

(22) Filed: Dec. 20, 2023

(30) Foreign Application Priority Data
Dec. 22, 2022 (KR) 10-2022-0182090

(51) Int. Cl. H10K 85/10; C08G 61/12; C08J 5/18; H10K 10/20; H10K 10/46; H10K 30/50

(52) U.S. Cl. CPC H10K 85/113; C08G 61/126; C08J 5/18; H10K 10/20; H10K 10/46; H10K 30/50; C08G 2261/124; C08G 2261/1412; C08G 2261/22; C08G 2261/3223; C08G 2261/3241; C08G 2261/3243; C08G 2261/92; C08J 2365/00

(57) ABSTRACT

Disclosed are a polymer including a structural unit represented by Chemical Formula 1, a structural unit represented by Chemical Formula 2, and a structural unit represented by Chemical Formula 3, an organic semiconductor material and a thin film including the polymer, and an electronic device including the thin film:

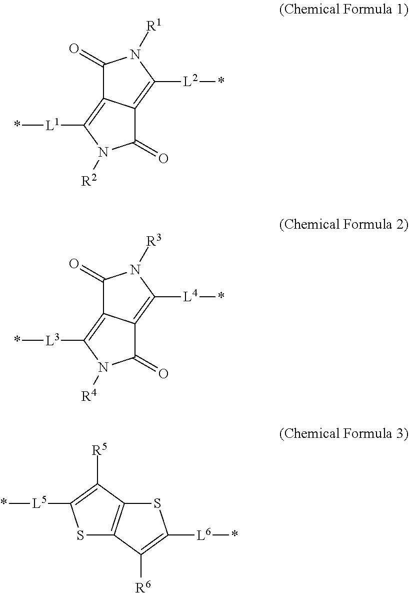

In Chemical Formulas 1 to 3,
the definitions of R¹ to R⁶, L¹ to L⁶, and * are as described in the specification.

### CROSS-REFERENCE TO RELATED APPLICATION

This application claims priority to and the benefit of Korean Patent Application No. 10-2022-0182090 filed in the Korean Intellectual Property Office on Dec. 22, 2022, the entire contents of which are incorporated herein by reference.

### BACKGROUND

### 1. Field

Polymers, organic semiconductor materials, and thin films including the polymers, and electronic devices including the organic semiconductor materials or thin films are disclosed.

### 2. Description of the Related Art

In recent years, research on stretchable display devices and/or a bio-attachable devices (such as a smart skin device, a soft robot, and/or a biomedical device) has been conducted. In addition to electrical characteristics, these devices should have stretchability in at least one direction according to external movements, and at the same time should be able to maintain their original performance after being restored to their original form. Therefore, a new material suitable for this is required.

### SUMMARY

Some example embodiments provide a new polymer with excellent electrical properties such as charge mobility and stretchability.

Some example embodiments provide an organic semiconductor material including the polymer.

Some example embodiments provide a thin film including the polymer.

Some example embodiments provide an electronic device including the organic semiconductor material or the thin film.

The polymer according to some example embodiments includes a structural unit represented by Chemical Formula 1, a structural unit represented by Chemical Formula 2, and a structural unit represented by Chemical Formula 3:

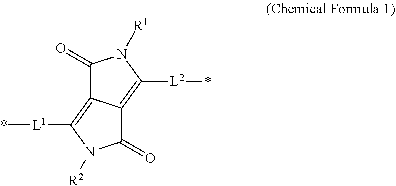

wherein, in Chemical Formula 1,
R1 and R2 are each independently a substituted or unsubstituted C1 to C40 linear alkyl group,
L1 and L2 are each independently a single bond, a substituted or unsubstituted C6 to C30 arylene group, a substituted or unsubstituted C2 to C20 heteroarylene group, or a combination thereof, and
* indicates a linking portion;

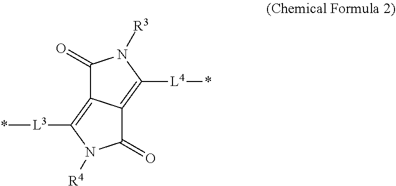

wherein, in Chemical Formula 2,
R3 and R4 are each independently a substituted or unsubstituted C3 to C40 branched alkyl group,
L3 and L4 are each independently a single bond, a substituted or unsubstituted C6 to C30 arylene group, a substituted or unsubstituted C2 to C20 heteroarylene group, or a combination thereof, and
* indicates a linking portion;

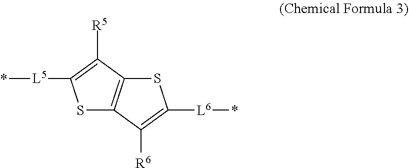

wherein, in Chemical Formula 3,
R5 and R6 are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C6 to C30 aryl group, a substituted or unsubstituted C7 to C30 arylalkyl group, a substituted or unsubstituted C6 to C30 aryloxy group, a substituted or unsubstituted C3 to C30 heterocyclic group, a halogen, or a cyano group,
L⁵ and L6 are each independently a single bond, a substituted or unsubstituted C6 to C30 arylene group, a substituted or unsubstituted C2 to C20 heteroarylene group, or a combination thereof, and
* indicates a linking portion.

In Chemical Formula 1, at least one of R1 and R2 may be a substituted or unsubstituted C5 to C30 linear alkyl group, and at least one of L1 and L2 may be a substituted or unsubstituted C6 to C20 arylene group, a substituted or unsubstituted C3 to C10 heteroarylene group, or a combination thereof.

In Chemical Formula 2, at least one of R3 and R4 may be a substituted or unsubstituted C5 to C35 branched alkyl group, and at least one of L3 and L4 may be substituted or unsubstituted C6 to C20 arylene group, a substituted or unsubstituted C3 to C10 heteroarylene group, or a combination thereof.

In Chemical Formula 3, at least one of R5 and R6 may be hydrogen, deuterium, a substituted or unsubstituted C1 to C20 alkyl group, a substituted or unsubstituted C6 to C20 aryl group, a substituted or unsubstituted C7 to C20 arylalkyl group, a halogen, or a cyano group, and at least one of L5 and L6 may be a single bond, a substituted or unsubstituted C6 to C20 arylene group, a substituted or unsubstituted C3 to C10 heteroarylene group, and/or a combination thereof.

In Chemical Formulas 1 to 3, at least one of L1 to L6 may be a single bond; electron donating moieties listed in Group 1; substituted or unsubstituted pyridine; substituted or unsubstituted pyrimidine; fused rings thereof; or a combination thereof:

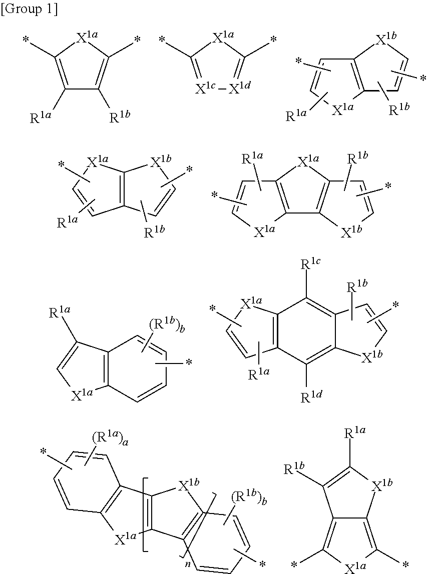

wherein, in Group 1,
X1a and X1b are each independently O, S, Se, or Te,
X1c and X1d are N, CRx, or SiRy,
X1e is O, S, Se, Te, NRv, CRwRx, or SiRyRz,
R1a, R1b, R1c, Rv, Rw, Rx, Ry, and Rz are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, or a cyano group, a and b are each independently integers from 1 to 4, n is 0, 1, or 2, and * is a linking point.

In Chemical Formulas 1 to 3, at least one of L1 to L6 may be a divalent linking group including a single bond; a substituted or unsubstituted furan, a substituted or unsubstituted thiophene, a substituted or unsubstituted selenophene, a substituted or unsubstituted tellurophene, a substituted or unsubstituted pyrrole, a substituted or unsubstituted benzene, a substituted or unsubstituted pyridine, a substituted or unsubstituted pyrimidine, or a fused ring in which two or more selected from these are fused to each other, and/or a combination thereof.

At least one of R1 and R2 may be an unsubstituted C10 to C30 linear alkyl group, at least one of R3 and R4 may be each independently an unsubstituted C10 to C35 branched alkyl group, R5 and R6 in Chemical Formula 3 may be each independently hydrogen, and at least one L1 to L6 may be a single bond, substituted or unsubstituted furan, substituted or unsubstituted thiophene, substituted or unsubstituted selenophene, or a combination thereof.

The polymer may include a structural unit represented by Chemical Formula 4 and a structural unit represented by Chemical Formula 5:

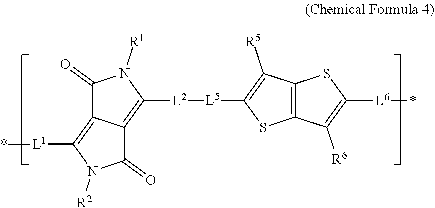

wherein, in Chemical Formula 4,
R1, R2, L1, and L2 are each as defined in Chemical Formula 1,
R5, R6, L5, and L6 are as defined in Chemical Formula 3, and
* indicates a linking portion;

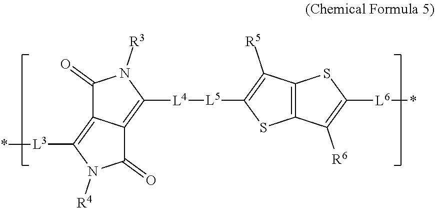

wherein, in Chemical Formula 5,
R3, R4, L3, and L4 are each as defined in Chemical Formula 2,
R5, R6, L5 and L6 are each as defined in Chemical Formula 3, and
* indicates a linking portion.

In Chemical Formula 4, at least one of R1 and R2 may be a substituted or unsubstituted C5 to C30 linear alkyl group, R5 and R6 are each independently hydrogen, deuterium, a substituted or unsubstituted C10 to C30 alkyl group, L1, L2, L5, and L6 are each independently a single bond, a substituted or unsubstituted C6 to C20 arylene group, a substituted or unsubstituted C3 to C10 heteroarylene group, or a combination thereof, in Chemical Formula 5, at least one of R³ and R⁴ may be a substituted or unsubstituted C5 to C35 branched alkyl group, R⁵ and R⁶ are each independently hydrogen, deuterium, substituted or unsubstituted C10 to C30 alkyl group, at least one of L³, L⁴, L⁵, and L⁶ may be a single bond, a substituted or unsubstituted C6 to C20 arylene group, a substituted or unsubstituted C3 to C10 heteroarylene group, and/or a combination thereof, and * indicates a linking portion.

In Chemical Formula 4, at least one of R1 and R2 may be a substituted or unsubstituted C10 to C30 linear alkyl group, R5 and R6 are both hydrogen, L1, L2, L5, and L6 are each independently a single bond, a substituted or unsubstituted C6 to C10 arylene group, a substituted or unsubstituted C3 to C10 heteroarylene group, or a combination thereof, in Chemical Formula 5, at least one of R3 and R4 may be a substituted or unsubstituted C10 to C35 branched alkyl group, R5 and R6 are both hydrogen, at least one of L3, L4, L5, and L6 may be a single bond, a substituted or unsubstituted C6 to C10 arylene group, a substituted or unsubstituted C3 to C10 heteroarylene group, and/or a combination thereof, and * indicates a linking portion.

The structural unit represented by Chemical Formula 1 and the structural unit represented by Chemical Formula 2 may exist in a molar ratio of about 1:99 to about 30:70 in the polymer.

The structural unit represented by Chemical Formula 4 and the structural unit represented by Chemical Formula 5 may exist in the polymer at a molar ratio of about 1:99 to about 30:70.

The polymer may include a plurality of polymer chains, and an average of a sum of the structural units represented by Chemical Formula 1 and Chemical Formula 2 may be 2,000 or less for the plurality of polymer chains.

The polymer may include a plurality of polymer chains, and an average of a sum of the structural units represented by Chemical Formula 4 and Chemical Formula 5 may be 2,000 or less for the plurality of polymer chains.

A number average molecular weight (Mn) of the polymer may be about 10,000 Da to about 500,000 Da.

An organic semiconductor material according to some example embodiments includes the polymer according to some example embodiments.

A thin film according to some example embodiments includes the polymer according to some example embodiments.

The thin film may further comprise an elastomer.

An electronic device according to some example embodiments includes a thin film according to some example embodiments.

The electronic device includes an organic diode, an organic thin film transistor, an organic solar cell, and/or an attachable device.

The polymer according to some example embodiments has excellent electrical properties such as charge mobility and can be used as an organic semiconductor material. In addition, the polymer has excellent solubility in solvents and can be easily manufactured into a thin film through a solution process. The manufactured thin film has stretchability and excellent electrical properties, and thus it can be advantageously applied to stretchable electronic devices.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1 to 3 are cross-sectional views each showing a thin film transistor according to some example embodiments.

FIGS. 4 to 6 are optical micrographs showing the presence or absence of cracks according to elongation rates of thin films manufactured from polymers synthesized in Synthesis Example 1, Comparative Synthesis Example 1, and Comparative Synthesis Example 3, respectively.

### DETAILED DESCRIPTION

Hereinafter, some example embodiments are described in detail so that those skilled in the art can easily implement them. Hereafter and in the following drawings, like reference numerals refer to like elements, and the sizes of elements in the drawings may be exaggerated for clarity and convenience of description. However, the actual applied structure may be implemented in various different forms and is not limited to the implementations described herein. Additionally, when the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

In order to clearly express various layers and areas in the drawing, the thickness is exaggerated or enlarged. Dimensions in the drawings may differ from actual dimensions. It will be understood that when an element such as a layer, film, region, or substrate is referred to as being “on” another element, it may be directly on the other element or intervening elements may also be present. In contrast, when an element is referred to as being “directly on” another element, there are no intervening elements present. Additionally, spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, device may be otherwise oriented, for example, rotated 90 degrees or at other orientations, and the spatially relative descriptors used herein should be interpreted accordingly.

As used herein, when a definition is not otherwise provided, “substituted” refers to replacement of a hydrogen atom of a compound by at least one substituent of halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or a combination thereof.

As used herein, when a definition is not otherwise provided, “hetero” refers to one including 1 to 4 atoms of N, O, S, Se, Te, Si, or P.

As used herein, when a definition is not otherwise provided, “alkyl group” refers to a C1 to C40 linear or branched, saturated, monovalent hydrocarbon group (e.g., methyl group, ethyl group, propyl group, isobutyl group, sec-butyl group, tert-butyl group, pentyl group, iso-amyl group, hexyl group, etc.).

As used herein, when a definition is not otherwise provided, “alkoxy group” refers to a C1 to C40 (e.g., C1 to C30) alkyl group linked through oxygen, for example, a methoxy, ethoxy, or sec-butoxy group.

As used herein, when a definition is not otherwise provided, “aryl group” refers to a monovalent functional group formed by the removal of one hydrogen atom from one or more rings of a C6 to C30 (e.g., C6 to C20) arene, e.g., a phenyl group or a naphthyl group. The arene refers to a hydrocarbon having an aromatic ring, and includes monocyclic and polycyclic hydrocarbons wherein the additional ring(s) of the polycyclic hydrocarbon may be aromatic or nonaromatic.

As used herein, when a definition is not otherwise provided, “heteroaryl group” includes at least one heteroatom such as N, O, S, Se, Te, Si, or P in the aforementioned aryl group such that the heteroaryl group includes at least one heteroatom replacing at least one of the carbon.

As used herein, when a definition is not otherwise provided, “aralkyl group” refers to a group represented by —(CR2aR2b)ₘAr, wherein m is an integer, R2a and R2b are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, or a cyano group, and Ar is the aforementioned aryl group or heteroaryl group.

As used herein, when a definition is not otherwise provided, “heterocyclic group” includes a group including at least one heteroatom such as N, O, S, Se, Te, Si, or P in a ring such as a C6 to C30 (e.g., C6 to C20) aryl group, a C3 to C30 (e.g., C3 to C20) cycloalkyl group, a fused ring thereof, and/or a combination thereof, with the at least one heteroatom replacing at least one of the carbon. When the heterocyclic group is a fused ring, a heteroatom may be included in the entire heterocyclic group or at least one of the rings.

As used herein, when a definition is not otherwise provided, “aromatic ring” refers to a functional group in which all atoms in the cyclic functional group have a p-orbital, and wherein these pi-orbitals are conjugated. For example, the aromatic ring may be a (e.g., C6 to C20) C6 to C30 aryl group or C3 to C30 (e.g., C3 to C20) heteroaryl group.

Hereinafter, a polymer according to some example embodiments is described.

The polymer according to some example embodiments includes structural units represented by Chemical Formulas 1 to 3:

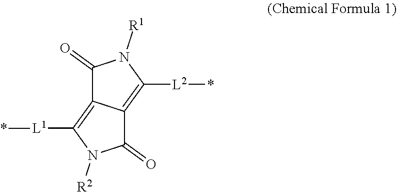

wherein, in Chemical Formula 1,
R1 and R2 are each independently a substituted or unsubstituted C1 to C40 linear alkyl group,
L1 and L2 are each independently a single bond, a substituted or unsubstituted C6 to C30 arylene group, a substituted or unsubstituted C2 to C20 heteroarylene group, and/or a combination thereof, and
* indicates linking portion;

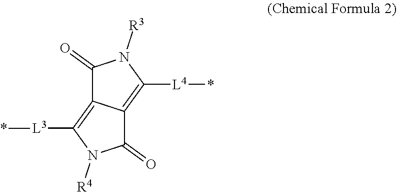

wherein, in Chemical Formula 2,
R3 and R4 are each independently a substituted or unsubstituted C3 to C40 branched alkyl group,
L3 and L4 are each independently a single bond, a substituted or unsubstituted C6 to C30 arylene group, a substituted or unsubstituted C2 to C20 heteroarylene group, and/or a combination thereof, and
* indicates linking portion;

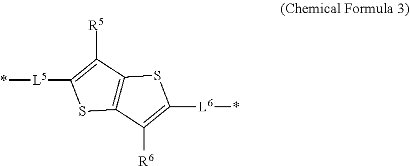

wherein, in Chemical Formula 3,
R5 and R6 are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C6 to C30 aryl group, a substituted or unsubstituted C7 to C30 arylalkyl group, a substituted or unsubstituted C6 to C30 aryloxy group, a substituted or unsubstituted C3 to C30 heterocyclic group, a halogen, or a cyano group,
L5 and L6 are each independently a single bond, a substituted or unsubstituted C6 to C30 arylene group, a substituted or unsubstituted C2 to C20 heteroarylene group, and/or a combination thereof, and
* indicates linking portion.

For example, the polymer according to some example embodiments is a terpolymer chain including the above three different structural units. However, the examples are not limited thereto, and in at least some embodiments, the polymer and/or polymer chains may further include additional structural units other than the above three structural units.

In the polymer according to some example embodiments, the structural unit represented by Chemical Formula 1 and the structural unit represented by Chemical Formula 2 are electron accepting moieties including a diketopyrrolopyrrole (DPP) core present between L1 and L2 and between L3 and L4 at both terminal ends, respectively.

Herein, in the structural unit represented by Chemical Formula 1, R1 and R2, each substituted on the nitrogen atom of the DPP core, are each independently a substituted or unsubstituted C1 to C40 linear alkyl group (for example, a C5 to C30 linear alkyl group, and/or a C10 to C30 linear alkyl group). In at least some embodiments, R1 and R2 may be the same or different from each other. The polymer including a DPP core substituted with such a linear alkyl group may have crystallinity. For this reason, a polymer including the structural unit represented by Chemical Formula 1 may have superior charge mobility.

In addition, in the structural unit represented by Chemical Formula 2, R3 and R4, each substituted on the nitrogen atom of the DPP core, are each independently a substituted or unsubstituted C3 to C40 branched alkyl group, for example, C5 to C35 branched alkyl group, for example, C10 to C35 branched alkyl group. In at least some embodiments, R3 and R4 may be the same or different from each other. The polymer including a DPP core substituted with such a branched alkyl group may have excellent solubility in solvents. For this reason, polymers including the structural unit represented by Chemical Formula 2 can be advantageously applied to thin film production through a solution process.

Accordingly, the polymer according to some example embodiments includes two types of electron accepting moieties each substituted with two different types of alkyl groups, so that due to the crystallinity and solubility properties imparted by each of these moieties, electrical properties such as charge mobility can be improved and solubility in solvents can be improved.

Meanwhile, the structural unit represented by Chemical Formula 3 is an electron donating moiety including a thieno[3,2-b]thiophene core between L5 and L6 present at both terminal ends.

Therefore, the polymer according to some example embodiments includes both the two types of electron accepting moieties and one type of electron donating moiety, thereby exhibiting higher charge mobility and additionally, it has excellent solubility in solvents, making it applicable as an organic semiconductor applicable to solution processes. The polymer according to this embodiment has flexibility due to its relatively low modulus, and therefore can be advantageously applied to various electronic devices requiring stretchability, such as organic diodes, organic thin film transistors, organic solar cells, and attachable devices. Meanwhile, L1 to L6 present at both terminal ends of each moiety are a linking group linking these moieties, and may be a single bond, or may include an aryl group, a heteroaryl group, and/or a combination thereof that has a conjugated structure with excellent electron mobility.

For example, in Chemical Formulas 1 to 3, L1 to L6 may each independently be a single bond, a substituted or unsubstituted C6 to C30 arylene group, a substituted or unsubstituted C3 to C10 heteroarylene group, and/or a combination thereof. For example, L1 to L6 may each independently be a substituted or unsubstituted C6 to C20 arylene group, a substituted or unsubstituted C3 to C10 heteroarylene group, and/or a combination thereof, or for example, a single bond, electron donating moieties listed in Group 1, a substituted or unsubstituted pyridine, a substituted or unsubstituted pyrimidine, a fused ring thereof, and/or a combination thereof:

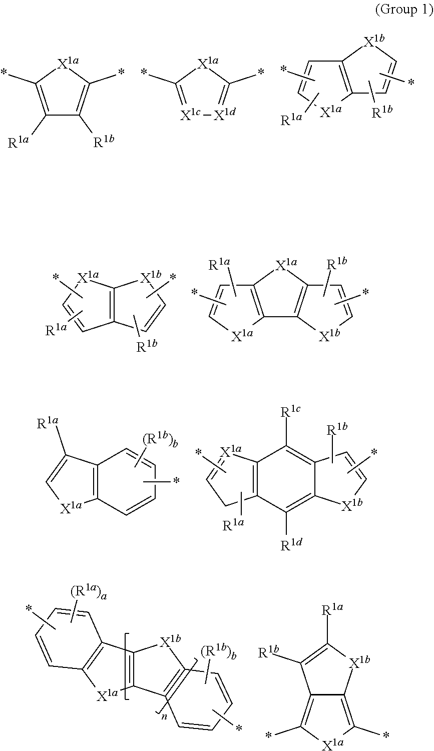

wherein, in Group 1,
X1a and X1b are each independently O, S, Se, or Te,
X1c and X1d are N, CRx, or SiRy,
X1e is O, S, Se, Te, NRv, CRwRx, or SiRyRz,
R1a, R1b, and R1c, and Rv, Rx, Ry, Rw, and Rz are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, or a cyano group,
a and b are each independently integers from 1 to 4,
n is 0, 1, or 2, and
* is a linking point.

For example, L1 to L6 may each independently be a divalent linking group including a single bond, at least one substituted or unsubstituted furan, at least one substituted or unsubstituted thiophene, at least one substituted or unsubstituted selenophene, at least one substituted or unsubstituted tellurophene, at least one substituted or unsubstituted pyrrole, at least one substituted or unsubstituted benzene, at least one substituted or unsubstituted pyridine, at least one substituted or unsubstituted pyrimidine, or a fused ring in which two or more selected from these are fused to each other, and/or a combination thereof.

In some example embodiments, L1 to L6 may each independently be a single bond, a substituted or unsubstituted furan, a substituted or unsubstituted thiophene, a substituted or unsubstituted selenophene, and/or a combination thereof.

The polymer may be, for example, a random copolymer, a block copolymer, or an alternating copolymer. In some example embodiments, the polymer may comprise a plurality of block copolymer chains.

In the polymer according to some example embodiments, the structural unit represented by Chemical Formula 1 and the structural unit represented by Chemical Formula 2 may be present in a molar ratio of about 1:99 to about 30:70 with respect to each other. For example, the structural unit represented by Chemical Formula 1 and the structural unit represented by Chemical Formula 2 may be present in a molar ratio of about 3:97 to about 25:75, about 5:95 to about 22:78, and about 5.3:94.7 to about 23:77, about 5.5:94.5 to about 20:80, about 10:90 to about 15:85, but are not limited to these ranges. By including the structural unit represented by Chemical Formula 1 and the structural unit represented by Chemical Formula 2 in the above ratio, the polymer according to some example embodiments may have excellent charge mobility and excellent solubility in a solvent.

The number average molecular weight (Mn) of the polymer according to some example embodiments is about 10,000 Da to about 500,000 Da. For example, the number average molecular weight (Mn) of the polymer may be about 20,000 Da to about 450,000 Da, about 20,000 Da to about 400,000 Da, about 30,000 Da to about 400,000 Da, about 40,000 Da to about 400,000 Da, about 40,000 Da to about 350,000 Da, about 40,000 Da to about 300,000 Da, about 40,000 Da to about 250,000 Da, about 40,000 Da to about 200,000 Da, about 50,000 Da to about 300,000 Da, about 50,000 Da to about 250,000 Da, about 50,000 Da to about 200,000 Da, about 50,000 Da to about 150,000 Da, about 50,000 Da to about 130,000 Da, about 50,000 Da to about 110,000 Da, about 50,000 Da to about 100,000 Da, about 50,000 Da to about 95,000 Da, about 50,000 Da to about 90,000 Da, about 50,000 Da to about 85,000 Da, about 50,000 Da to about 80,000 Da, about 55,000 Da to about 80,000 Da, about 55,000 Da to about 75,000 Da, about 55,000 Da to about 70,000 Da, and/or about 60,000 Da to about 70,000 Da, but is not limited to these ranges.

When the number average molecular weight (Mn) of the polymer according to some example embodiments is within the above range, the polymer may have excellent solubility in a solvent, and at the same time, the charge mobility of a thin film manufactured therefrom may be improved.

The polymer dispersity index (PDI) according to some example embodiments may be about 2.5 to about 3.5. The polymer dispersity index of a polymer can be calculated as “weight average molecular weight (Mw)”÷“number average molecular weight (Mn).”

The measurement of the weight average molecular weight (Mw) and number average molecular weight (Mn) is not particularly limited, and known methods can be used or known methods can be appropriately modified. For example, the number average molecular weight (Mn) and weight average molecular weight (Mw) of the polymer according to some example embodiments are measured using polystyrene as a standard material and using SEC (Size Exclusion Chromatography), etc.

As the polymer according to some example embodiments has a number average molecular weight (Mn) in the above range, it has excellent solubility in solvents and can be advantageously applied to thin film production through a solution process. If the number average molecular weight of the polymer according to some example embodiments is larger than the above range, the solubility of the polymer in a solvent may decrease, making it difficult to apply it to a solution process. In addition, if the number average molecular weight of the polymer is less than the above range, it may be difficult to manufacture a thin film of the desired thickness from the polymer through a solution process, and the electrical and mechanical properties of the produced thin film may deteriorate.

Additionally, the total number of structural units represented by Chemical Formula 1 and structural units represented by Chemical Formula 2 in the polymer may be about 2,000 or less for a representative polymer chain included in the polymer. For example, an average (e.g., mean, mode, and/or median) sum of the structural units represented by Chemical Formula 1 and structural units represented by Chemical Formula 2 for each of the plurality of may be about 2,000 or less. When the number of structural units represented by Chemical Formulas 1 and 2 is within the above ranges, it may be easy to adjust the number average molecular weight of the polymer including these structural units and the structural unit represented by Chemical Formula 3 to the above range.

Meanwhile, as can be seen from the Examples and Comparative Examples described later, the charge mobility of the thin film manufactured from the polymer according to some example embodiments may be about 0.6 cm2/Vs or more, for example, about 0.65 cm2/Vs or more. Considering that a charge mobility of a thin film manufactured from a polymer that does not include the structural unit represented by Chemical Formula 1 among the structural units forming the polymer according to some example embodiments, but consists only of the structural unit represented by Chemical Formula 2 and the structural unit represented by Chemical Formula 3 is less than 0.6 cm2/Vs, it is believed that the polymer according to some example embodiments further includes a structural unit represented by Chemical Formula 1, which may be detrimental to solubility, may render a thin film manufactured therefrom a further increased charge mobility due to crystallinity imparted by the structural unit represented by Chemical Formula 1.

In addition, the polymer according to some example embodiments that includes a structural unit represented by Chemical Formula 1, contrary to the expectation that crystallinity may be imparted to the polymer and solubility may be reduced, may also have excellent solubility in solvents. Therefore, the polymer according to some example embodiments can exhibit better electrical properties due to increased charge mobility while maintaining excellent solubility. Therefore, thin films manufactured from such polymers through a solution process can exhibit excellent electrical properties, and, therefore, can be advantageously applied as organic semiconductors.

Meanwhile, both terminal ends of the polymer may be capped with an aryl group such as a phenyl group, or a heteroaryl group such as thiophene, but are not limited thereto.

In some example embodiments, the polymer may include a structural unit represented by Chemical Formula 4, and a structural unit represented by Chemical Formula 5:

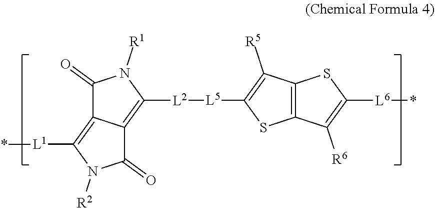

wherein, in Chemical Formula 4,
R1, R2, L1, and L2 are each as defined in Chemical Formula 1, and
R5, R6, L5, and L6 are as defined in Chemical Formula 3;

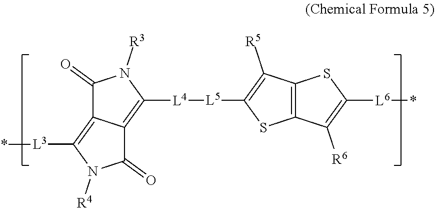

wherein, in Chemical Formula 5,
R3, R4, L3, and L4 are each as defined in Chemical Formula 2, and
R5, R6, L5 and L6 are each as defined in Chemical Formula 3.

According to some example embodiments, the polymer, which is a terpolymer including structural units represented by Chemical Formulas 1 to 3, may be a polymer including polymer chains comprising structural units represented by Chemical Formulas 4 and 5. Herein, the structural unit represented by Chemical Formula 4 is a structural unit that is a combination of the structural unit represented by Chemical Formula 1 and the structural unit represented by Chemical Formula 3, and the structural unit represented by Chemical Formula 5 is a polymer in which the structural unit represented by Chemical Formula 2 and the structural unit represented by Chemical Formula 3 are combined. That is, the polymer according to some example embodiments may be a polymer, such as a block copolymer, that includes a first structural unit or first block represented by Chemical Formula 4 in which an electron accepting moiety, a linear alkyl group substituted in DPP (hereinafter referred to as ‘first electron accepting moiety’ or ‘A1’) and an electron donating moiety (hereinafter referred to as ‘electron donating moiety’ or ‘D’) are linked to each other, and a second structural unit or second block represented by Chemical Formula 5 in which an electron accepting moiety, a branched alkyl group substituted in DPP (hereinafter referred to as ‘second electron accepting moiety’ or ‘A2’) and an electron donating moiety (hereinafter referred to as ‘electron donating moiety’ or ‘D’) are linked to each other.

Both the first structural unit and the second structural unit each include one electron accepting moiety and one electron donating moiety, and thus a copolymer in which these structural units or blocks are linked in an alternating arrangement of electron accepting moieties (A1 or A2) and electron donating moieties (D), for example, one or more *-[L1-A1-L2-L5-D-L6]-* and one or more *-[L3-A2-L4-L5-D-L6]-* are arranged alternately may have better charge mobility. In addition, such a copolymer in which electron accepting moieties and electron donating moieties are arranged alternately may have excellent stretchability when manufactured into a thin film. Accordingly, thin films manufactured from these copolymers may be stretchable thin films.

In Chemical Formulas 4 and 5, the definitions of R1 to R6, and L1 to L6 are the same as those defined in Chemical Formulas 1 to 3, respectively, and thus detailed descriptions thereof are omitted.

In some example embodiments, in Chemical Formula 4, R1 and R2 may each independently be a substituted or unsubstituted C5 to C30 linear alkyl group, R5 and R6 may each independently be hydrogen, deuterium, substituted or unsubstituted C10 to C30 alkyl group, and L1, L2, L5, and L6 may each independently be a single bond, a substituted or unsubstituted C6 to C20 arylene group, a substituted or unsubstituted C3 to C10 heteroarylene group, and/or a combination thereof.

In some example embodiments, in Chemical Formula 5, R3 and R4 may each independently be a substituted or unsubstituted C5 to C35 branched alkyl group, R5 and R6 may each independently be hydrogen, deuterium, or a substituted or unsubstituted C10 to C30 alkyl group, and L3, L4, L5, and L6 may each independently be a single bond, a substituted or unsubstituted C6 to C20 arylene group, a substituted or unsubstituted C3 to C10 heteroarylene group, and/or a combination thereof.

In addition, in some example embodiments, in Chemical Formula 4, R1 and R2 may each independently be a substituted or unsubstituted C10 to C30 linear alkyl group, R5 and R6 may be all hydrogen, and L1, L2, L5, and L6 may each independently be a single bond, a substituted or unsubstituted C6 to C10 arylene group, a substituted or unsubstituted C3 to C10 heteroarylene group, and/or a combination thereof, and/or in Chemical Formula 5, R3 and R4 may each independently be a substituted or unsubstituted C10 to C35 branched alkyl group, R5 and R6 are all hydrogen, and L3, L4, L5, and L6 may each independently be a single bond, a substituted or unsubstituted C6 to C10 arylene group, a substituted or unsubstituted C3 to C10 heteroarylene group, and/or a combination thereof.

In some example embodiments, the structural unit represented by Chemical Formula 4 and the structural unit represented by Chemical Formula 5 may be present in a molar ratio of about 1:99 to about 30:70. For example, the structural unit represented by Chemical Formula 4 and the structural unit represented by Chemical Formula 5 may be present in a molar ratio of about 3:97 to about 25:75, about 5:95 to about 22:78, and about 5.3:94.7 to about 23:77, about 5.5:94.5 to about 20:80, or about 10:90 to about 15:85, but is not limited to these ranges. By including the structural unit represented by Chemical Formula 4 and the structural unit represented by Chemical Formula 5 in the above ratio, the polymer according to some example embodiments may have excellent charge mobility and excellent solubility in solvents.

In at least some embodiments, a total number of structural units represented by Chemical Formula 4 and structural units represented by Chemical Formula 5 may be about 2,000 or less for a representative polymer chain included in the polymer. For example, an average (e.g., mean, mode, and/or median) of a sum of the structural units represented by Chemical Formula 4 and structural units represented by Chemical Formula 5 for each of the plurality of may be about 2,000 or less. By maintaining the total number of these structural units at about 2,000 or less, the number average molecular weight of the polymer can be appropriately adjusted within the number average molecular weight range of the polymer according to the above-described embodiments.

As described above, the polymer according to some example embodiments has excellent electrical properties such as charge mobility and also has excellent solubility in solvents, which is advantageous for manufacturing thin films by a solution process, and thus, may be advantageously applied as an organic semiconductor material with excellent electrical properties and flexibility.

Accordingly, an organic semiconductor material according to some example embodiments includes the polymer according to some example embodiments.

The organic semiconductor material may further include the polymer according to some example embodiments and any additional components required for preparing the organic semiconductor from the polymer. For example, such additional components may be a solvent for dissolving the polymer, a binder, an elastomer, etc., and may further include additional components for imparting additional characteristics to the organic semiconductor produced.

The solvent may include, for example, a solvent selected based on a capability of dissolving and/or dispersing the polymer according to some example embodiments and not reacting with the polymer. For example, a solvent may be any solvent generally used for dissolving a polymer in the technical field to which the present invention pertains, and may be for example, any organic solvent having a relatively low boiling point which is heated and removed at a low temperature and leaves little and/or a non-detectable solvent residue.

Examples of such a solvent may be, for example, an aromatic or aliphatic hydrocarbon, a halogenated hydrocarbon, an ester, or an ether amide solvent, and specific examples thereof may include, for example, chloroform, tetrachloroethane, tetrahydrofuran, toluene, tetralin, decalin, anisole, xylene, ethyl acetate, methyl ethyl ketone, dimethyl formamide, chlorobenzene, dichlorobenzene, trichlorobenzene, propylene glycol monomethyl ether acetate (PGMEA), and/or a combination thereof, but is not limited these examples. In some example embodiments, the solvent may include xylene, toluene, tetralin, decalin, chloroform, chlorobenzene, ortho-dichlorobenzene, trichlorobenzene, and/or a combination thereof, but is not limited to these examples.

The binder may improve dispersibility of the polymer according to some example embodiments, and may include, for example, polystyrene, etc., but is not limited thereto.

The elastomer may be mixed with a polymer according to some example embodiments to improve stretchability of an organic semiconductor prepared therefrom, and may include, for example, an organic elastomer, an organic-inorganic elastomer, an inorganic elastomer-like material, and/or a combination thereof. Examples of the organic elastomer or organic/inorganic elastomer may include substituted or unsubstituted polyorganosiloxane such as polydimethylsiloxane; an elastomer including a substituted or unsubstituted butadiene moiety such as styrene-ethylene-butylene-styrene (SEBS), styrene-ethylene-propylene-styrene (SEPS), styrene-butadiene-styrene (SBS), styrene-isoprene-styrene (SIS), and styrene-isobutylene-styrene (SIBS); an elastomer containing a urethane moiety; an elastomer including an acrylic moiety; an elastomer including an olefin moiety, and/or a combination thereof, but are not limited thereto. The inorganic elastomer-like material may include, but is not limited to, ceramic, solid metal, liquid metal, and/or a combination thereof having elasticity.

The organic semiconductor material may be coated on a substrate (and/or the like) in a solution and/or suspension state to be manufactured into a thin film. The method of coating the solution and/or suspension on the substrate may include any method known in the art, for example spin-coating, dip-coating, screen printing, microcontact printing, doctor blading, and/or the like, but is not limited thereto.

As described above, the organic semiconductor material according to some example embodiments may be coated on a substrate and then dried and/or cured to form a thin film, and the thin film thus produced may be used as, for example, an organic semiconductor.

Accordingly, some example embodiments provide a thin film made from the polymer according to some example embodiments or the organic semiconductor material according to some example embodiments. The thin film may have stretchability and excellent charge mobility characteristics of the polymer according to some example embodiments, and, thus, may be a stretchable organic semiconductor thin film. Due to its stretching properties, the thin film may flexibly respond to external forces or external movements such as twisting, pressing, and pulling, and may easily be restored to its original state.

An elastic modulus of the stretchable organic semiconductor thin film according to some example embodiments may be, for example, less than about 107 Pa, and within the above range, for example, may be about 10 Pa or more and less than about 107 Pa. For example, an elongation rate of the stretchable organic semiconductor thin film may be greater than or equal to about 10%, and within the above range, about 10% to about 1000%, about 10% to about 800%, about 10% to 500%, about 10% to about 300%, about 10% to about 200%, about 10% to about 100%, about 10% to about 90%, about 10% to about 80%, about 10% to about 70%, about 10% to about 60%, about 10% to about 50%, about 10% to about 40%, about 20% to about 70%, about 20% to about 60%, about 20% to about 50%, or about 20% to about 40%.

Herein, the elongation rate may be a percentage change in length from the initial length of the thin film to the breaking point. According to some example embodiments, the stretchable organic semiconductor thin film may have a relatively small change in electrical properties when stretched. For example, when the stretchable organic semiconductor thin film is stretched by about 30%, the change in charge mobility of the stretchable organic semiconductor thin film may be less than or equal to about 10%, less than or equal to about 8%, less than or equal to about 7%, less than or equal to about 5%, less than or equal to about 3%, less than or equal to about 2%, or less than or equal to about 1%.

The polymer according to some example embodiments can be advantageously applied to a solution process due to its excellent solubility in solvents, but the method of manufacturing the organic semiconductor thin film is not necessarily limited to a solution process. For example, the organic semiconductor thin film may be a deposited thin film formed by vapor deposition.

The organic semiconductor thin film according to some example embodiments has excellent electrical properties due to high charge mobility and stretchability, and can be applied to various electronic devices that require such properties. Accordingly, an electronic device according to some example embodiments includes the organic semiconductor thin film according to some example embodiments.

Examples of the electronic device include, for example, an organic photoelectric device, an organic light-emitting device, or an organic diode including an organic sensor; organic thin film transistor; an attachable device such as biometric sensors; a device including such electronic devices; and/or the like.

The electronic device may be applied to a bendable display panel, a foldable display panel, a rollable display panel, a wearable device, a skin-like display panel, a skin-like sensor, a large-area conformable display, smart clothing, and/or the like, but is not limited thereto.

Hereinafter, an example of a thin film transistor including an organic semiconductor thin film according to some example embodiments will be described with reference to the drawings. In the drawings, the thickness of layers, films, panels, regions, etc., are exaggerated for clarity. The same reference numerals are given to the same parts throughout the specification.

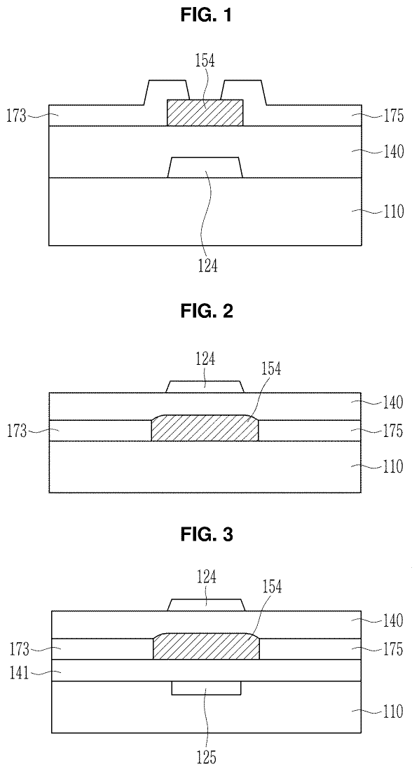

FIGS. 1 to 3 are cross-sectional views of each thin film transistor according to some example embodiments.

Referring to FIGS. 1 to 3, a thin film transistor according to some embodiments includes a gate electrode 124, an organic semiconductor 154 overlapped with the gate electrode 124, a gate insulating layer 140 between the gate electrode 124 and the organic semiconductor 154, and a source electrode 173 and a drain electrode 175 electrically connected to the organic semiconductor 154.

First, referring to FIG. 1, a thin film transistor according to some example embodiments may be a thin film transistor having a bottom gate and top contact structure. Specifically, a thin film transistor according to an embodiment includes a gate electrode 124 on the substrate 110; a gate insulating layer 140 on the gate electrode 124; an organic semiconductor 154 on the gate insulating layer 140; and a source electrode 173 and a drain electrode 175 electrically connected to the organic semiconductor 154.

The substrate 110 may be made of, e.g., transparent glass, silicon, polymer, and/or the like; and a gate electrode 124 is formed on the substrate 110. The gate electrode 124 may be connected to a gate line (not shown) configured to transfer a gate signal. The gate electrode 124 may be made of a conductive material such as gold (Au), copper (Cu), nickel (Ni), aluminum (Al), molybdenum (Mo), chromium (Cr), tantalum (Ta), titanium (Ti), an alloy thereof, or a combination thereof, but is not limited thereto. For example, in at least some embodiments, the conductive material may include a carbon based conductive material, such as graphene, a conductive polymer, and/or the like.

The gate insulating layer 140 is disposed on the gate electrode 124. The gate insulating layer 140 may be made of an organic material or an inorganic material. Examples of the organic material may include a soluble polymer compound such as a polyvinyl alcohol-based compound, a polyimide-based compound, a polyacryl-based compound, a polystyrene-based compound, benzocyclobutane (BCB), styrene-ethylene-butylene-styrene (SEBS), and/or the like. Examples of the inorganic material may include a silicon nitride (SiNx), silicon oxide (SiO2), and/or the like.

The organic semiconductor 154 is disposed on the gate insulating layer 140. The organic semiconductor 154 may be formed from an organic semiconductor material including the polymer according to some example embodiments, and may be the aforementioned stretchable organic semiconductor thin film and/or include the polymer including the units represented by Chemical Formulas 1 to 3. The organic semiconductor 154 can be formed by preparing the aforementioned organic semiconductor material in a solution form and using a solution process such as spin coating, slit coating, or inkjet printing. Alternatively, the organic semiconductor 154 can be formed by vacuum deposition or thermal deposition of the aforementioned organic semiconductor material.

The source electrode 173 and drain electrode 175 are disposed on the organic semiconductor 154. The source electrode 173 and the drain electrode 175 face the gate electrode 124 on the organic semiconductor 154 as the center. The source electrode 173 may be connected to a data line (not shown) configured to transmit a data signal. The source electrode 173 and the drain electrode 175 may include at least one conductive material such as gold (Au), copper (Cu), nickel (Ni), aluminum (Al), molybdenum (Mo), chromium (Cr), tantalum (Ta), titanium (Ti), or an alloy, and/or a combination thereof, but is not limited thereto. For example, in at least some embodiments, the source electrode 173 and the drain electrode 175 may include a carbon based conductive material.

Referring to FIG. 2, the thin film transistor according to some example embodiments, unlike the thin film transistor disclosed in FIG. 1, may be a thin film transistor with a top gate and top contact structure. Specifically, a thin film transistor according to some example embodiments includes an organic semiconductor 154 on the substrate 110; a source electrode 173 and a drain electrode 175 electrically connected to the organic semiconductor 154; a gate insulating layer 140 on the organic semiconductor 154, the source electrode 173, and the drain electrode 175; and a gate electrode 124 on the gate insulating layer 140.

Referring to FIG. 3, the thin film transistor according to an embodiment may be a thin film transistor having a dual gate and bottom/top contact structure, unlike the aforementioned embodiment. Specifically, a thin film transistor according to some embodiments includes an organic semiconductor 154 on the substrate 110; a first gate electrode 125 positioned under the organic semiconductor 154; a second gate electrode 124 positioned on the organic semiconductor 154; a first gate insulating layer 141 between the organic semiconductor 154 and the first gate electrode 125; a second gate insulating layer 140 between the organic semiconductor 154 and the second gate electrode 124; and a source electrode 173 and a drain electrode 175 electrically connected to the organic semiconductor 154. The first gate electrode 125 may be buried in the substrate 110 or may be formed by impurity doping. The first gate electrode 125, the organic semiconductor 154, and the second gate electrode 124 may overlap with each other.

Although examples of thin film transistors have been described here, they are not limited to these, and the organic semiconductor thin film according to some example embodiments can be equally applied to thin film transistors of all structures.

Thin film transistors may be applied to various electronic devices as a switching device and/or a driving device in various electronic devices, including but not limited to a liquid crystal display device, an organic light emitting display device, a quantum dot display device, an electrophoretic display device, an organic photoelectric device, an organic sensor, and/or the like. The electronic device may be, for example, a flexible or stretchable electronic device, and may be a wearable device and/or a skin type device.

Hereinafter, embodiments of the present disclosure will be described in more detail through examples. However, the following examples are for illustrative purposes only and do not limit the scope of the present invention.

### EXAMPLES

### Synthesis Example 1: Synthesis of Polymer Represented by Chemical Formula A-1

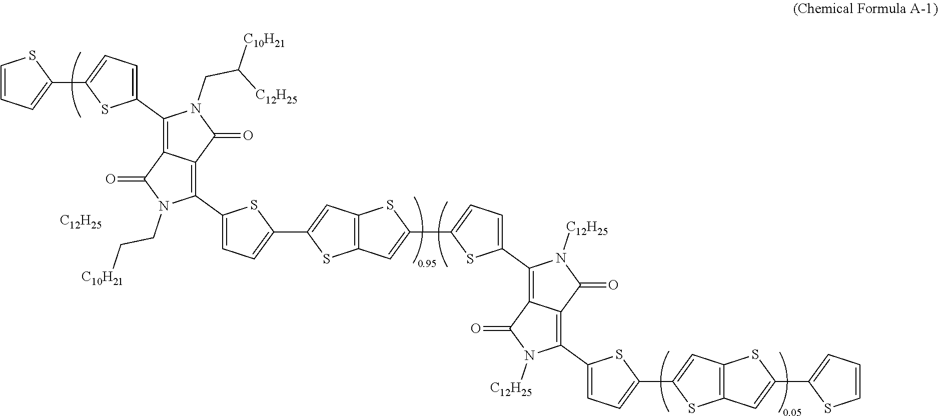

A polymer represented by Chemical Formula A-1 is synthesized in the following method.

3,6-bis(5-bromothiophen-2-yl)-2,5-bis(2-decyltetradecyl)-2,5-dihydropyrrolo[3,4-c]pyrrole-1,4-dione (215.0 mg, 0.19 mmol, 0.95 eq.), 3,6-bis(5-bromothiophen-2-yl)-2,5-didodecyl-2,5-dihydropyrrolo[3,4-c] pyrrole-1,4-dione (7.9 mg, 0.01 mmol, 0.05 eq.), TT-Sn (2,5-bis(trimethylstannyl)thieno[3,2-b]thiophene) (93.2 mg, 0.2 mmol, 1 eq.), Pd2(dba)3 (tris(dibenzylideneacetone)dipalladium (0) (3.7 mg, 0.004 mmol, 0.02 eq.), and P(o-tol)3 {tri(o-tolyl)phosphine} (4.9 mg, 0.016 mmol, 0.08 eq.) are added to a 50 ml round-bottomed flask and then, sealed, and chlorobenzene (10 ml) and nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated), and the polymer is precipitated in methanol. The polymer is filtered therefrom and dried under high vacuum for 24 hours (with a yield: 59%).

The obtained polymer has a number average molecular weight (Mn) of 74 KDa, a weight average molecular weight (Mw) of 200 Kda, polymer dispersity index (PDI) of 2.70. An elemental analysis result thereof is as follows (%): C 72.7, H 8.63, N 2.26 (Ca. 5.3 mol % C12-DPPT-TT segment).

### Synthesis Example 2: Synthesis of Polymer Represented by A-2

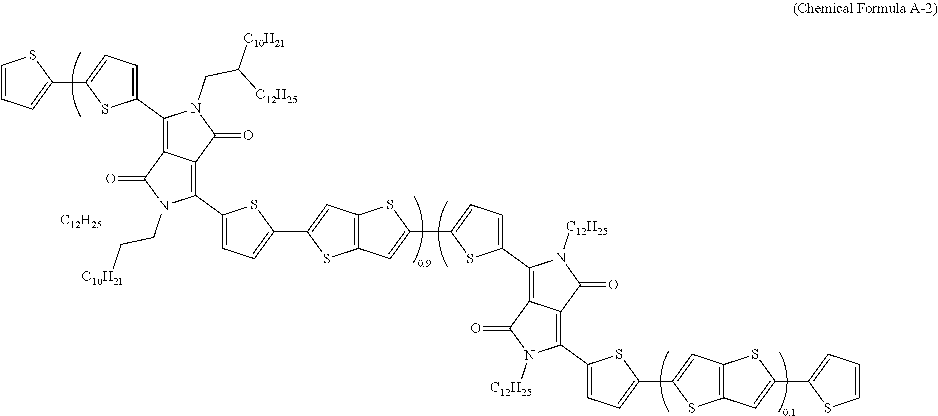

A polymer represented by Chemical Formula A-2 is synthesized in the following method.

3,6-bis(5-bromothiophen-2-yl)-2,5-bis(2-decyltetradecyl)-2,5-dihydropyrrolo[3,4-c]pyrrole-1,4-dione (203.7 mg, 0.18 mmol, 0.9 eq.), 3,6-bis(5-bromothiophen-2-yl)-2,5-didodecyl-2,5-dihydropyrrolo[3,4-c]pyrrole-1,4-dione (15.9 mg, 0.02 mmol, 0.1 eq.), TT-Sn (2,5-bis(trimethylstannyl)thieno[3,2-b]thiophene) (93.2 mg, 0.2 mmol, 1 eq.), Pd₂(dba)₃ (tris(dibenzylideneacetone)dipalladium (0) (3.7 mg, 0.004 mmol, 0.02 eq.), and P(o-tol)₃ {tri(o-tolyl)phosphine} (4.9 mg, 0.016 mmol, 0.08 eq.) are added to a 50 ml round-bottomed flask and then, sealed, and chlorobenzene (10 ml) and nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated), and the polymer is precipitated in methanol. The polymer is filtered therefrom and dried under high vacuum for 24 hours (a yield: 52%).

The obtained polymer has a number average molecular weight (Mn) of 66 Kda, a weight average molecular weight (Mw) of 180 Kda, polymer dispersity index (PDI) of 2.75. The polymer has an elemental analysis result as follows (%): C 72.9, H 8.62, N 2.37 (Ca. 10.3 mol % C₁₂-DPPT-TT segment).

### Synthesis Example 3: Synthesis of Polymer Represented by A-3

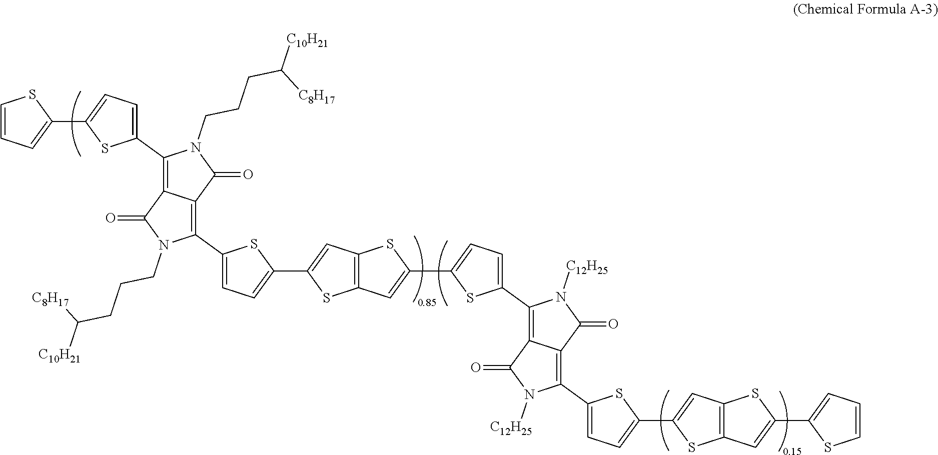

A polymer represented by Chemical Formula A-3 is synthesized in the following method.

3,6-bis(5-bromothiophen-2-yl)-2,5-bis(4-octyltetradecyl)-2,5-dihydropyrrolo[3,4-c]pyrrole-1,4-dione (182.8 mg, 0.17 mmol, 0.85 eq.), 3,6-bis(5-bromothiophen-2-yl)-2,5-didodecyl-2,5-dihydropyrrolo[3,4-c]pyrrole-1,4-dione (23.85 mg, 0.03 mmol, 0.15 eq.), TT-Sn (2,5-bis(trimethylstannyl)thieno[3,2-b]thiophene) (93.2 mg, 0.2 mmol, 1 eq.), Pd2(dba)3 (tris(dibenzylideneacetone)dipalladium (0) (3.7 mg, 0.004 mmol, 0.02 eq.), and P(o-tol)3 {tri(o-tolyl)phosphine} (4.9 mg, 0.016 mmol, 0.08 eq.) are added to a 50 ml round-bottomed flask and then, sealed, and chlorobenzene (10 ml) and nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated), and the polymer is precipitated in methanol. The polymer is filtered therefrom and dried under high vacuum for 24 hours (a yield: 51%).

The obtained polymer has a number average molecular weight (Mn) of 69 Kda, a weight average molecular weight (Mw) of 227 Kda, and polymer dispersity index (PDI) of 3.27. The polymer has an elemental analysis result as follows (%): C 71.4, H 8.41, N 2.49 (Ca. 14.5 mol % C12-DPPT-TT segment).

### Synthesis Example 4: Synthesis of Polymer Represented by Chemical Formula A-4

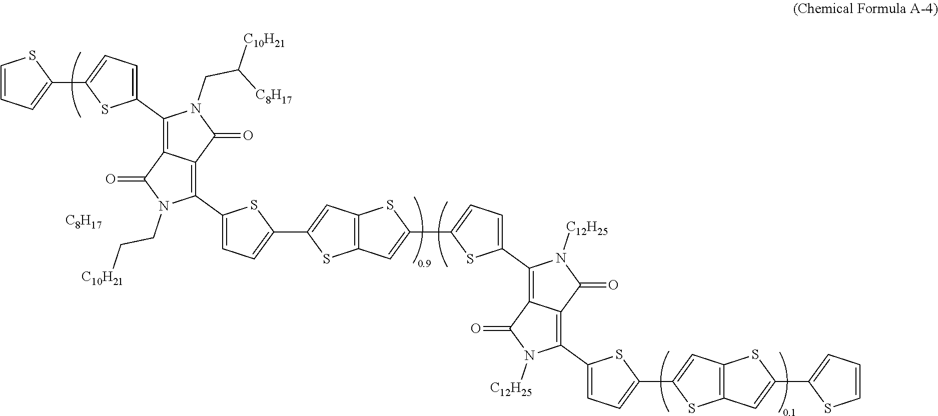

A polymer represented by Chemical Formula A-4 is synthesized in the following method.

3,6-bis(5-bromothiophen-2-yl)-2,5-bis(2-octyldodecyl)-2,5-dihydropyrrolo[3,4-c]pyrrole-1,4-dione (183.5 mg, 0.18 mmol, 0.9 eq.), 3,6-bis(5-bromothiophen-2-yl)-2,5-didodecyl-2,5-dihydropyrrolo[3,4-c]pyrrole-1,4-dione (15.9 mg, 0.02 mmol, 0.1 eq.), TT-Sn (2,5-bis(trimethylstannyl)thieno[3,2-b]thiophene) (93.2 mg, 0.2 mmol, 1 eq.), Pd2(dba)3 (tris(dibenzylideneacetone)dipalladium (0) (3.7 mg, 0.004 mmol, 0.02 eq.), and P(o-tol)3 {tri(o-tolyl)phosphine} (4.9 mg, 0.016 mmol, 0.08 eq.) are added to a 50 ml round-bottomed flask and then, sealed, and chlorobenzene (10 ml) and nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated), and the polymer is precipitated in methanol. The polymer is filtered therefrom and dried under high vacuum for 24 hours (a yield: 58%).

The obtained polymer has a number average molecular weight (Mn) of 55 Kda, a weight average molecular weight (Mw) of 179 Kda, polymer dispersity index (PDI) of 3.28. The polymer has an elemental analysis result as follows (%): C 71.4, H 8.42, N 2.71 (Ca. 10.5 mol % C12-DPPT-TT segment).

### Comparative Synthesis Example 1: Synthesis of Polymer Represented by Chemical Formula B-1

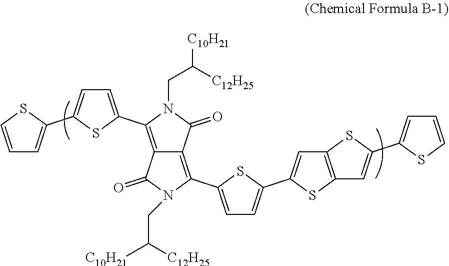

A polymer represented by Chemical Formula B-1 is synthesized in the following method.

3,6-bis(5-bromothiophen-2-yl)-2,5-bis(2-decyltetradecyl)-2,5-dihydropyrrolo[3,4-c]pyrrole-1,4-dione (226.3 mg, 0.2 mmol, 1 eq.), TT-Sn (2,5-bis(trimethylstannyl)thieno[3,2-b]thiophene) (93.2 mg, 0.2 mmol, 1 eq.), Pd2(dba)3 (tris(dibenzylideneacetone)dipalladium (0) (3.7 mg, 0.004 mmol, 0.02 eq.), and P(o-tol)3 {tri(o-tolyl)phosphine} (4.9 mg, 0.016 mmol, 0.08 eq.) are added to a 50 ml round-bottomed flask and then, sealed, and chlorobenzene (10 ml) and nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated), and the polymer is precipitated in methanol. The polymer is filtered therefrom and dried under high vacuum for 24 hours (a yield: 57%).

The obtained polymer has a number average molecular weight (Mn) of 46 Kda, a weight average molecular weight (Mw) of 122 Kda, and polymer dispersity index (PDI) of 2.67.

### Comparative Synthesis Example 2: Synthesis of Polymer Represented by Chemical Formula B-2

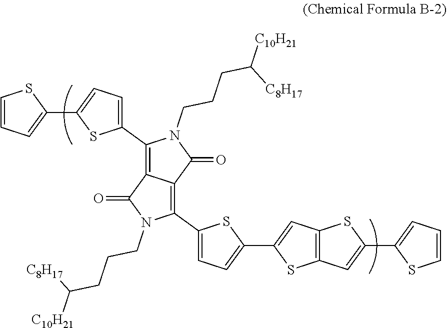

A polymer represented by Chemical Formula B-2 is synthesized in the following method.

3,6-bis(5-bromothiophen-2-yl)-2,5-bis(4-octyltetradecyl)-2,5-dihydropyrrolo[3,4-c]pyrrole-1,4-dione (193.6 mg, 0.18 mmol, 0.9 eq.), TT-Sn (2,5-bis(trimethylstannyl)thieno[3,2-b]thiophene) (93.2 mg, 0.2 mmol, 1 eq.), Pd2(dba)3 (tris(dibenzylideneacetone)dipalladium (0) (3.7 mg, 0.004 mmol, 0.02 eq.), and P(o-tol)3 {tri(o-tolyl)phosphine} (4.9 mg, 0.016 mmol, 0.08 eq.) are added to a 50 ml round-bottomed flask and then, sealed, and chlorobenzene (10 ml) filled with nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated), and the polymer is precipitated in methanol. The polymer is filtered therefrom and dried under high vacuum for 24 hours (a yield: 48%).

The obtained polymer has a number average molecular weight (Mn) of 34 Kda, a weight average molecular weight (Mw) of 99 Kda, and polymer dispersity index (PDI) of 2.92.

### Comparative Synthesis Example 3: Synthesis of Polymer Represented by Chemical Formula B-3

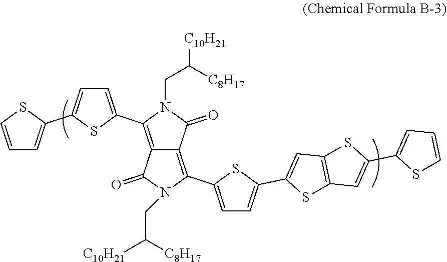

A polymer represented by Chemical Formula B-3 is synthesized in the following method.

3,6-bis(5-bromothiophen-2-yl)-2,5-bis(2-octyldodecyl)-2,5-dihydropyrrolo[3,4-c]pyrrole-1,4-dione (183.5 mg, 0.18 mmol, 0.9 eq.), TT-Sn (2,5-bis(trimethylstannyl)thieno[3,2-b]thiophene) (93.2 mg, 0.2 mmol, 1 eq.), Pd₂(dba)₃ (tris(dibenzylideneacetone)dipalladium (0) (3.7 mg, 0.004 mmol, 0.02 eq.), and P(o-tol)₃ {tri(o-tolyl)phosphine} (4.9 mg, 0.016 mmol, 0.08 eq.) are added to a 50 ml round-bottomed flask and then, sealed, and chlorobenzene (10 ml) and nitrogen is added thereto. After sealing the round-bottomed flask again, a reaction proceeds at 115° C. for 40 hours.

In order to cap the polymer, 2-(tributylstannyl)thiophene (0.2 mmol) is added thereto and then, reacted at 115° C. for 4 hours, and 2-bromothiophene (0.2 mmol) is added thereto and then, further reacted at 115° C. for 4 hours. Subsequently, after precipitation with methanol and filtration, the polymer is loaded onto a Soxhlet thimble and washed with methanol, acetone, hexane, and methylchloride in order (each for 8 hours or more).

The polymer is finally obtained from chloroform (e.g., the chloroform solution thereof is concentrated, and the polymer is precipitated in methanol. The polymer is filtered therefrom and dried under high vacuum for 24 hours (a yield: 66%).

The obtained polymer has a number average molecular weight (Mn) of 65 Kda, a weight average molecular weight (Mw) of 246 Kda, and polymer dispersity index (PDI) of 3.78.

### Preparation Example 1: Manufacture of Thin Film

Each of the polymers of Synthesis Example 1 and Comparative Synthesis Examples 1 and 3 is dissolved in chlorobenzene at a concentration of 5 mg/ml and then, spin-coated on an n-octadecyltrimethoxysilane (OTS)-modified SiO2 substrate and heat-treated at 150° C. for 30 minutes under a nitrogen atmosphere to form a thin film including each polymer according to the synthesis example and the comparative synthesis examples.

### Preparation Example 2: Manufacture of Thin Film Transistor

A substrate doped with Si at high concentration is used as a gate electrode, and a SiO2 insulating layer (gate insulating layer, 300 nm) is formed on the gate electrode. After a surface treatment of the formed gate insulating layer with n-octadecyltrimethoxysilane (OTS), the polymers of Synthesis Examples 1 to 4, and Comparative Synthesis Examples 1 to 3 are added to chlorobenzene at a concentration of 0.5 wt % to obtain polymer solutions, respectively and the polymer solutions are spin-coated to be 300 Å thick at 1000 rpm and heat-treated at 130° C. for 1 hour under a nitrogen atmosphere to form active layers (length: 50 μm, width: 1000 μm). Subsequently, gold (Au) is thermally deposited on the active layer to form a source electrode and a drain electrode, thereby manufacturing thin film transistors according to Examples 1 to 4 and Comparative Examples 1 to 3.

### Evaluation I: Evaluation of Stretching Properties

Each of the thin films of Preparation Example 1 respectively including the polymers according to Synthesis Example 1 and Comparative Synthesis Examples 1 and 3 is transferred onto a PDMS substrate and then, stretched by using a stretching station to evaluate stretching properties. The stretching properties are evaluated by observing crack onset strain according to elongation rate (0% to 50%) with an optical microscope (Leica DM4000 M LED).

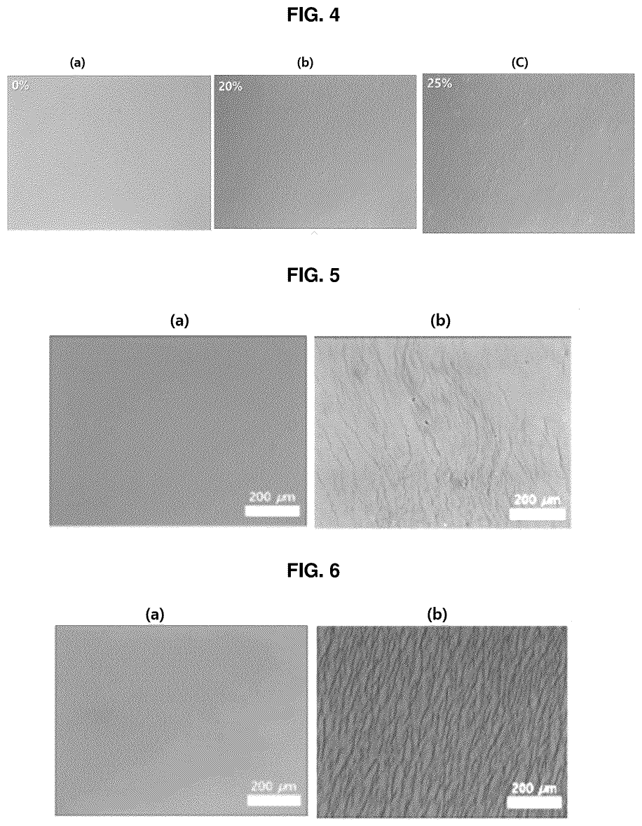

FIGS. 4 to 6 are optical micrographs showing the presence or absence of cracks according to elongation rates of thin films manufactured from polymers synthesized in Synthesis Example 1 (FIG. 4), Comparative Synthesis Example 1 (FIG. 5), and Comparative Synthesis Example 3 (FIG. 6), respectively.

Referring to FIG. 4, the thin film including the polymer of Synthesis Example 1 according to some example embodiments exhibits no cracks before the stretching, that is, at an elongation rate of 0% (refer to (a) of FIG. 4) and an elongation rate of 20% (refer to (b) of FIG. 4) but a few very small cracks (refer to (b) of FIG. 4).

On the other hand, the thin films including the polymers according to Comparative Synthesis Examples 1 and 3, which includes not DPP substituted with a linear alkyl group according to some example embodiments but DPP substituted with a branched alkyl group alone as an electron acceptor, as shown from FIGS. 5 and 6, all exhibit lots of cracks on the surface at the elongation rate of 20% (refer to (b) of FIG. 5 and (b) of FIG. 6)

In particular, as shown in (b) of FIG. 6, in the thin film including the polymer according to Comparative Synthesis Example 3, cracks uniformly occur over the entire surface at the elongation rate of 20%, and in the thin film including the polymer according to Comparative Synthesis Example 1 shown in FIG. 5, long cracks occur over the entire surface at the elongation rate of 20%. (a) of FIG. 5 and (a) of FIG. 6 show each surface of the thin films respectively including the polymers of Comparative Synthesis Example 1 and Comparative Synthesis Example 3 before the stretching. In other words, the thin films including the polymers synthesized in Comparative Synthesis Examples 1 and 3 exhibit no cracks on the surface at the elongation rate of 0%, thereby illustrating that the cracks are a result of the elongation.

Accordingly, the thin film including the polymer according to some example embodiments exhibits much more excellent stretching properties, compared with the thin films including the polymers according to the comparative synthesis examples.

### Evaluation II: Measurement of Charge Mobility of Thin Film Transistor

The charge mobility of the thin film transistors according to Examples 1 to 4 and Comparative Examples 1 to 3 manufactured in Preparation Example 2 is measured using KEITHLEY's Semiconductor Characterization System (4200-SCS), and the results are shown in Table 1.

TABLE 1

| | Charge mobility (cm²/Vs) |
|---|---|
| Example 1 | 0.70 |
| Example 2 | 0.68 |
| Example 3 | 0.79 |
| Example 4 | 0.90 |
| Comparative Example 1 | 0.44 |
| Comparative Example 2 | 0.32 |
| Comparative Example 3 | 0.58 |

As shown in Table 1, the thin film transistors of Examples 1 to 4 manufactured by using the polymer according to some example embodiments exhibit charge mobility ranging from a minimum of 0.68 cm2/Vs to a maximum of 0.90 cm2/Vs, but the thin film transistors of Comparative Examples 1 to 3 exhibit charge mobility of 0.58 cm2/Vs at most, which is much lower than the minimum charge mobility of the thin film transistors of the examples.

In other words, the thin film transistors including a polymer including DPP substituted with a linear alkyl group providing crystallinity to the polymer as a substituent substituting a nitrogen atom of DPP (diketopyrrolopyrrole) as a portion of an electron accepting moiety according to some example embodiments exhibits significantly improved charge mobility, compared with the thin film transistors including an electron accepting moiety consisting of DPP substituted with a branched alkyl group alone without DPP substituted with the linear alkyl group according to the comparative examples. In addition, the thin film transistors of the examples, which are manufactured by dissolving the polymer in a solvent, maintain solubility of the polymer, which is not reduced at all, compared with that of the polymer of the comparative example.

Based on these results, the polymer according to some example embodiments exhibits high charge mobility as well as maintains excellent solubility and thus may be advantageously applied as an organic semiconductor material with much improved electrical properties.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A polymer, comprising:
a structural unit represented by Chemical Formula 1;
a structural unit represented by Chemical Formula 2; and
a structural unit represented by Chemical Formula 3, 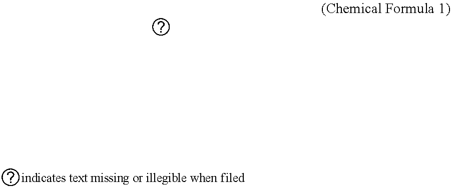
wherein, in Chemical Formula 1,
R¹ and R² are, each independently, a substituted or unsubstituted C1 to C40 linear alkyl group,
L¹ and L² are, each independently, a single bond, a substituted or unsubstituted C6 to C30 arylene group, a substituted or unsubstituted C2 to C20 heteroarylene group, or a combination thereof, and
* indicates a linking portion; 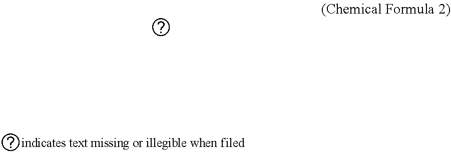
wherein, in Chemical Formula 2,
R³ and R⁴ are, each independently, a substituted or unsubstituted C3 to C40 branched alkyl group,
L³ and L⁴ are, each independently, a single bond, a substituted or unsubstituted C6 to C30 arylene group, a substituted or unsubstituted C2 to C20 heteroarylene group, or a combination thereof, and
* indicates a linking portion; 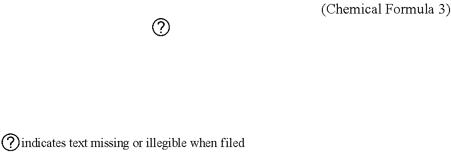
wherein, in Chemical Formula 3,
R⁵ and R⁶ are, each independently, hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C6 to C30 aryl group, a substituted or unsubstituted C7 to C30 arylalkyl group, a substituted or unsubstituted C6 to C30 aryloxy group, a substituted or unsubstituted C3 to C30 heterocyclic group, a halogen, or a cyano group,
L⁵ and L⁶ are, each independently, a single bond, a substituted or unsubstituted C6 to C30 arylene group, a substituted or unsubstituted C2 to C20 heteroarylene group, or a combination thereof, and
* indicates linking portion.

2. The polymer of claim 1, wherein at least one of R¹ and R² is a substituted or unsubstituted C5 to C30 linear alkyl group, and at least one of L¹ and L² is a substituted or unsubstituted C6 to C20 arylene group, a substituted or unsubstituted C3 to C10 heteroarylene group, or a combination thereof.

3. The polymer of claim 1, wherein at least one of R³ and R⁴ is a substituted or unsubstituted C5 to C35 branched alkyl group, and at least one of L³ and L⁴ is a substituted or unsubstituted C6 to C20 arylene group, a substituted or unsubstituted C3 to C10 heteroarylene group, or a combination thereof.

4. The polymer of claim 1, wherein at least one of R⁵ and R⁶ is hydrogen, deuterium, a substituted or unsubstituted C1 to C20 alkyl group, a substituted or unsubstituted C6 to C20 aryl group, a substituted or unsubstituted C7 to C20 arylalkyl group, a halogen, or a cyano group, and L⁵ and L⁶ are, each independently, a single bond, a substituted or unsubstituted C6 to C20 arylene group, a substituted or unsubstituted C3 to C10 heteroarylene group, or a combination thereof.

5. The polymer of claim 1, wherein at least one of L¹ to L⁶ is a single bond, electron donating moieties listed in Group 1, a substituted or unsubstituted pyridine, a substituted or unsubstituted pyrimidine, a fused ring thereof, or a combination thereof: 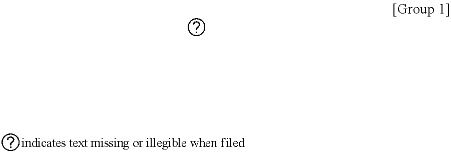
wherein, in Group 1,
X^{1a} and X^{1b} are, each independently, O, S, Se, or Te,
X^{1c} and X^{1d} are, each independently, N, CR^{x}, or SiR^{y},
X^{1e} is O, S, Se, Te, NR^{v}, CR^{w}R^{x}, or SiR^{y}R^{z},
R^{1a}, R^{1b}, R^{1c}, R^{v}, R^{w}, R^{x}, R^{y}, and R^{z} are, each independently, hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, or a cyano group,
a and b are, each independently, integers from 1 to 4,
n is 0, 1, or 2, and
* is a linking point.

6. The polymer of claim 1, wherein at least one of L¹ to L⁶ is a divalent linking group including a single bond; a substituted or unsubstituted furan, a substituted or unsubstituted thiophene, a substituted or unsubstituted selenophene, a substituted or unsubstituted tellurophene, a substituted or unsubstituted pyrrole, a substituted or unsubstituted benzene, a substituted or unsubstituted pyridine, a substituted or unsubstituted pyrimidine, a fused ring in which two or more selected from these are fused to each other, or a combination thereof.

7. The polymer of claim 1, wherein
R¹ and R² are, each independently, an unsubstituted C10 to C30 linear alkyl group,
R³ and R⁴ are, each independently, an unsubstituted C10 to C35 branched alkyl group,
R⁵ and R⁶ are, each independently, hydrogen, and
L¹ to L⁶ are, each independently, a single bond, a substituted or unsubstituted furan, a substituted or unsubstituted thiophene, a substituted or unsubstituted selenophene, or a combination thereof.

8. The polymer of claim 1, wherein the polymer includes a structural unit represented by Chemical Formula 4, and a structural unit represented by Chemical Formula 5:

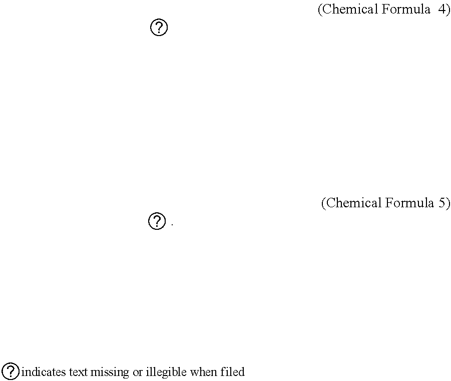

9. The polymer of claim 8, wherein
at least one of R¹ and R² is a substituted or unsubstituted C5 to C30 linear alkyl group,
at least one of R⁵ and R⁶ is hydrogen, deuterium, a substituted or unsubstituted C10 to C30 alkyl group,
at least one of L¹, L², L⁵, and L⁶ is a single bond, a substituted or unsubstituted C6 to C20 arylene group, a substituted or unsubstituted C3 to C10 heteroarylene group, and/or a combination thereof,
at least one of R³ and R⁴ is a substituted or unsubstituted C5 to C35 branched alkyl group,
at least one of R⁵ and R⁶ is hydrogen, deuterium, a substituted or unsubstituted C10 to C30 alkyl group, and
at least one of L³, L⁴, L⁵, and L⁶ is a single bond, a substituted or unsubstituted C6 to C20 arylene group, a substituted or unsubstituted C3 to C10 heteroarylene group, or a combination thereof.

10. The polymer of claim 8, wherein
at least one of R¹ and R² is a substituted or unsubstituted C10 to C30 linear alkyl group,
R⁵ and R⁶ are all hydrogen, and
at least one of L¹, L², L⁵, and L⁶ is a single bond, a substituted or unsubstituted C6 to C10 arylene group, a substituted or unsubstituted C3 to C10 heteroarylene group, or a combination thereof,
at least one of R³ and R⁴ is a substituted or unsubstituted C10 to C35 branched alkyl group,
R⁵ and R⁶ are all hydrogen, and
at least one of L³, L⁴, L⁵, and L⁶ is a single bond, a substituted or unsubstituted C6 to C10 arylene group, a substituted or unsubstituted C3 to C10 heteroarylene group, or a combination thereof.

11. The polymer of claim 1, wherein the structural unit represented by Chemical Formula 1 and the structural unit represented by Chemical Formula 2 are present in a molar ratio of about 1:99 to about 30:70.

12. The polymer of claim 8, wherein the structural unit represented by Chemical Formula 4 and the structural unit represented by Chemical Formula 5 are present in a molar ratio of about 1:99 to about 30:70.

13. The polymer of claim 1, wherein
the polymer includes a plurality of polymer chains, and
an average of a sum of the structural units represented by Chemical Formula 1 and Chemical Formula 2 is 2,000 or less for the plurality of polymer chains.

14. The polymer of claim 8, wherein
the polymer includes a plurality of polymer chains, and
an average of a sum of the structural units represented by Chemical Formula 4 and Chemical Formula 5 is 2,000 or less for the plurality of polymer chains.

15. The polymer of claim 1, wherein a number average molecular weight (Mn) of the polymer is about 10,000 Da to about 500,000 Da.

16. An organic semiconductor material comprising the polymer of claim 1.

17. A thin film comprising the polymer of claim 1.

18. The thin film of claim 17, further comprising:
an elastomer.

19. An electronic device comprising the thin film of claim 17.

20. The electronic device of claim 19, wherein electronic device includes at least one of an organic diode, an organic thin film transistor, an organic solar cell, or an attachable device.
